(19) United States
(12) Patent Application Publication
(10) Pub. No.: US 2026/0255925 A1
(43) Pub. Date: Aug. 27, 2026

(54) WAFER ROTATING MECHANISM, WAFER ROTATING AND CLAMPING MECHANISM, WAFER CLEANING SYSTEM AND WAFER DRYING SYSTEM

(71) Applicant: HANGZHOU SIZONE ELECTRONIC TECHNOLOGY INC., Zhejiang (CN)

(72) Inventors: Xiaoyu XU, Zhejiang (CN); Dongzhou ZHENG, Zhejiang (CN); Xuannan CHEN, Zhejiang (CN); Qi YIN, Zhejiang (CN)

(73) Assignee: HANGZHOU SIZONE ELECTRONIC TECHNOLOGY INC., Zhejiang (CN)

(21) Appl. No.: 18/879,235

(22) PCT Filed: Jan. 9, 2023
(86) PCT No.: PCT/CN2023/071168

§ 371 Date: Dec. 26, 2024

(30) Foreign Application Priority Data
Jun. 27, 2022 (CN) 202210732735.8

(51) Int. Cl. H10P 72/76; H10P 72/00

(52) U.S. Cl. CPC H10P 72/7608; H10P 72/0408; H10P 72/7624

(57) ABSTRACT

Disclosed is a wafer rotating mechanism, comprising: a lower mechanism, used for outputting rotating power; and an upper mechanism, connected to a wafer rotating base; wherein, the upper mechanism and the lower mechanism have an operation state and a separation state; in the operation state, the upper mechanism is driven by the lower mechanism to rotate; in the separation state, the upper mechanism is separated from the lower mechanism; in a power-off condition, the upper mechanism and the lower mechanism are switched from the operation state to the separation state, and the upper mechanism drives the wafer rotating base to rotate under the action of inertia until the wafer rotating base stops. Further disclosed are a wafer rotating and clamping mechanism, a wafer drying system and a wafer cleaning system.

### TECHNICAL FIELD

The invention belongs to the technical field of fabrication of semiconductor integrated circuit chips, and particularly relates to a wafer rotating mechanism, a wafer rotating and clamping mechanism, a wafer cleaning system and a wafer drying system.

### BACKGROUND

With the continuous development of the electronic industry and the semiconductor industry, the requirements for the surface quality and processing accuracy of semiconductor silicon wafers, ceramic and optical glass become increasingly higher, boosting the emergence of more advanced wafer processing devices. In an existing semiconductor processing process, some devices such as single wafer cleaner and cleaning and drying systems adopt a wafer rotating mechanism. The wafer rotating mechanism of these devices clamp wafers by means of a centrifugal force, i.e. a wafer is fixed to a base that can rotate at a high speed, then the base is driven by a motor to rotate at a high speed, and a clamping device clamps the wafer under the action of the centrifugal force. For example, the wafer cleaning and drying system fulfills a drying effect by shaking liquid off from wafers under the action of a centrifugal force. Furthermore, in some cases, the rotatable base is directly driven by a servo motor. Although such an approach can fulfill a simple structure and reliable transmission, it has an obvious defect: when the device is powered off, the motor will stop instantly or slow down quickly, and at this moment, the wafer may be disengaged from the clamping mechanism and fractured, bringing a great impact on normal use of the device.

### BRIEF SUMMARY OF THE INVENTION

To overcome the defects in the prior art, the invention provides a wafer rotating mechanism that can drive a wafer rotating base to continue rotating by means of an upper mechanism in case of a power outage to allow a wafer to slow down gradually before being brought to a halt so as to prevent the wafer from being fractured, and also provides a wafer rotating and clamping mechanism, a wafer cleaning system, and a wafer drying system.

The technical solution adopted by the invention to solve the above mentioned technical problems is as follows: a wafer rotating mechanism comprises:
a lower mechanism, used for outputting rotating power; and
an upper mechanism, connected to a wafer rotating base;
wherein, the upper mechanism and the lower mechanism have an operation state and a separation state; in the operation state, the upper mechanism is driven by the lower mechanism to rotate; in the separation state, the upper mechanism is separated from the lower mechanism;
in a power-off condition, the upper mechanism and the lower mechanism are switched from the operation state to the separation state, and the upper mechanism drives the wafer rotating base to rotate under the action of inertia until the wafer rotating base stops.

Further, the lower mechanism and a power source are arranged separately, and the lower mechanism is able to rotate with the power source.

Further, in the power-off condition, the lower mechanism stops outputting the rotating power.

Further, a clutch structure is arranged between the upper mechanism and the lower mechanism, and in a power-on condition, the lower mechanism and the upper mechanism are in noncontact transmission connection by means of the clutch structure, such that the lower mechanism drives the upper mechanism to rotate synchronously.

Further, the clutch structure comprises contact surfaces which are respectively arranged on the lower mechanism and the upper mechanism, and an electromagnetic induction assembly, and when the electromagnetic induction assembly is powered on, a repelling force is generated between the lower mechanism and the upper mechanism to realize noncontact transmission connection between the lower mechanism and the upper mechanism.

Further, the electromagnetic induction assembly comprises electromagnets arranged on the lower mechanism at intervals and permanent magnets arranged on the upper mechanism at intervals, and the permanent magnets and the electromagnets are the same in magnetic polarity and are arranged alternately.

Further, a clutch structure is arranged between the upper mechanism and the lower mechanism, and the lower mechanism and the upper mechanism are in contact transmission connection by means of the clutch structure, such that the lower mechanism drives the upper mechanism to rotate synchronously.

Further, the clutch structure comprises a magnet and a metal part which are respectively arranged on the upper mechanism and the lower mechanism, and a reset element, and in the power-off condition, the magnet is disconnected from the metal part.

Further, the clutch structure comprises an upper contact surface arranged on the upper mechanism, a lower contact surface arranged on the lower mechanism, and an elastic element and a push rod, and the elastic element drives the lower contact surface and the upper contact surface to come in contact to realize transmission; and in the power-off condition, the push rod drives the lower contact surface or the upper contact surface to compress the elastic element to separate the upper contact surface from the lower contact surface.

Further, the clutch structure comprises an upper toothed disc arranged on the upper mechanism and a lower toothed disc arranged on the lower mechanism, and the upper toothed disc engages with the lower toothed disc to realize transmission.

Further, the clutch structure comprises a push rod and a groove which are respectively arranged on the upper mechanism and the lower mechanism, and in the power-off condition, the push rod disengages from the groove to separate the upper mechanism from the lower mechanism.

Further, in the separation state, the distance ranges between the upper mechanism and the lower mechanism is 0.1-5 mm.

The invention further discloses a wafer rotating and clamping mechanism, comprising the wafer rotating mechanism, a wafer rotating base, a wafer supporting mechanism arranged on a periphery of the wafer rotating base, and a wafer clamping mechanism, wherein under power-off condition, the upper mechanism and the lower mechanism are switched from the operation state to the separation state, the upper mechanism drives the wafer rotating base to rotate under the action of inertia, a bottom of the wafer clamping mechanism moves outwards under the action of a centrifugal force, an end of the wafer clamping mechanism presses against the wafer to fix the wafer together with the wafer supporting mechanism, and when the wafer rotating base stops, the rotating clamping mechanism releases the wafer.

The invention further discloses a wafer drying system, comprising the said wafer rotating and clamping mechanism.

The invention further discloses a wafer cleaning system, comprising the said wafer rotating and clamping mechanism.

The invention has the following benefits: (1) when the wafer rotating and clamping mechanism is powered on, the lower mechanism connected to the power source is rigidly connected to the upper mechanism where the wafer rotating and clamping mechanism is located by means of the clutch structure, such that transmission is stable and reliable; (2) in case of a sudden power outage, the clutch structure can instantly disconnect the upper mechanism from the lower mechanism, and the upper mechanism where the wafer rotating and clamping mechanism is located will not be affected by the braking force of a motor and can slow down to stop gradually, thus ensuring the stability of a wafer and preventing the wafer from being fractured; (3) there is no friction or impact between execution parts of the noncontact clutch structure, such that fewer impurity particles will be generated, and the risk of damage of the clutch structure is lowered; (4) in a case where the clutch structure adopting the electromagnetic induction assembly is used, the electromagnets can respond quickly (approx. 14 ms) and can be demagnetized instantly when power is cut off, so the upper mechanism where the wafer rotating and clamping mechanism is located will not be affected by the braking force of a motor; (5) in a case where the clutch structure adopting friction discs is used, the instant friction is reduced by a force perpendicular to the contact surface, and transmitted torque is reduced instantly, such that the upper mechanism where the wafer rotating and clamping mechanism is located can enter an inertial rotation state instantly; (6) in a case where the clutch structure adopting the upper and lower toothed discs or eject pins is used, clutch surfaces come in contact in the form of slopes; when the toothed discs are engaged, the upper and lower clutch surfaces can be smoothly combined under the guidance of the slopes; when the toothed discs are separated, the clutch surface on a claw side can slide way from the clutch surface on a motor side by means of the slopes to realize disengagement.

### BRIEF DESCRIPTION OF THE DRAWINGS

FIG. 1 is a schematic diagram of an upper mechanism and a lower mechanism of a wafer rotating mechanism in an operation state according to the invention.

FIG. 2 is a schematic diagram of the upper mechanism and the lower mechanism of the wafer rotating mechanism in a separation state according to the invention.

FIG. 3 is a front view of a wafer rotating and clamping mechanism according to Embodiment 1 of the invention.

FIG. 4 is a schematic diagram of a clutch structure in an operation state according to Embodiment 1 of the invention.

FIG. 5 is an A-A sectional view of an upper mechanism and a lower mechanism in an operation state according to Embodiment 2 of the invention.

FIG. 6 is an A-A sectional view of the upper mechanism and the lower mechanism in a separation state according to Embodiment 2 of the invention.

FIG. 7 is a front view of an upper mechanism and a lower mechanism in a separation state according to Embodiment 3 of the invention.

FIG. 8 is a sectional view of the upper mechanism and the lower mechanism in the separation state according to Embodiment 3 of the invention.

FIG. 9 is a front view of the upper mechanism and the lower mechanism in an operation state according to Embodiment 3 of the invention.

FIG. 10 is a sectional view of the upper mechanism and the lower mechanism in the operation state according to Embodiment 3 of the invention.

FIG. 11 is a front view of an upper mechanism and a lower mechanism in a separation state according to Embodiment 4 of the invention.

FIG. 12 is a front view of an upper toothed disc and a lower toothed disc in a separation state according to Embodiment 4 of the invention.

FIG. 13 is a front view of the upper mechanism and the lower mechanism in an operation state according to Embodiment 4 of the invention.

FIG. 14 is a front view of the upper toothed disc and the lower toothed disc in an engaged state according to Embodiment 4 of the invention.

FIG. 15 is a sectional view of an upper mechanism and a lower mechanism in an operation state according to Embodiment 5 of the invention.

### DETAILED DESCRIPTION OF THE INVENTION

To allow those skilled in the art to gain a better understanding of the technical solutions of the invention, the technical solutions in the embodiments of the invention will be clearly and completely described below in conjunction with accompanying drawings of these embodiments. Obviously, the embodiments described below are merely illustrative ones, and are not all possible ones of the invention. All other embodiments obtained by those ordinarily skilled in the art based on the following ones without creative labor should also fall within the protection scope of the invention.

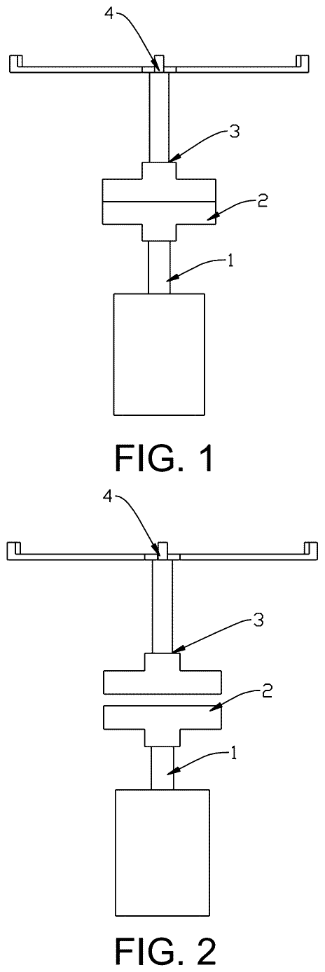

As shown in FIGS. 1 and 2, a wafer rotating mechanism comprises a power source 1, a lower mechanism 2 connected to the power source 1, and an upper mechanism 3 connected to a wafer rotating base 4, wherein the lower mechanism 2 is able to rotate with the power source 1, and in actual use, the lower mechanism 2 rotates at a high speed over 1000 rpm in most cases; and specifically, the power source 1 may be a motor output shaft. The lower mechanism 2 and the power source 1 are separated. Of course, in other embodiments, the power source 1 and the lower mechanism 2 may be integrated structure as long as the power source 1 can output rotating power to the lower mechanism 2.

The upper mechanism 3 and the lower mechanism 2 have an operation state and a separation state. In the operation state, the upper mechanism 3 is driven by the lower mechanism 2 to rotate, or the upper mechanism 3 and the lower mechanism 2 rotate synchronously at a high speed. In the separation state, the upper mechanism 3 is separated from the lower mechanism 2, that is, the upper mechanism 3 cannot receive power output by the lower mechanism 2.

In a power-off condition, the upper mechanism 3 and the lower mechanism 2 are switched from the operation state to the separation state, at this moment, the lower mechanism 2 stops outputting rotating power, that is, the power source 1 and the lower mechanism 2 stop rotating, or the rotation speed of the power source 1 and the lower mechanism 2 decreases drastically, but the upper mechanism 3 still drives the wafer rotating base 4 to rotate under the action of inertia until the wafer rotating base 4 stops. In other words, because the upper mechanism 3 is disconnected from the lower mechanism 2, the upper mechanism 3 will not stop slowly or instantly with the lower mechanism 2 and will continue to rotate without an external force under the action of inertia.

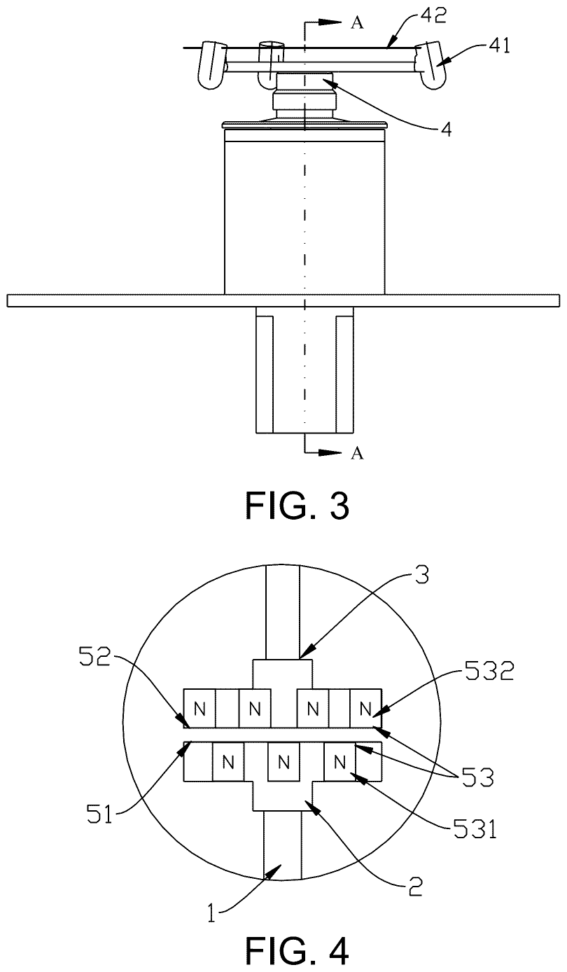

As shown in FIG. 3, a wafer rotating and clamping mechanism comprises the wafer rotating mechanism, a wafer rotating base, a wafer supporting mechanism arranged on the periphery of the wafer rotating base, and a wafer clamping mechanism 41. The wafer supporting mechanism and the wafer clamping mechanism 42 may be existing structures. The wafer clamping mechanism 41 is featured with a center of gravity close to the bottom, so when the wafer clamping mechanism 41 rotates circumferentially with the wafer rotating base, the bottom of the wafer clamping mechanism 41 will tilt upwards to make the wafer clamping mechanism 41 change from an original vertical state to an approximately horizontal state, and at this moment, an upper end of the wafer clamping mechanism 41 presses against a wafer 42.

In a power-off condition, the upper mechanism 3 and the lower mechanism 2 are switched from the operation state to the separation state, the upper mechanism 3 drives the wafer rotating base 4 to rotate under the action of inertia, the bottom of the wafer clamping mechanism 41 moves outwards and tilts upwards under the action of a centrifugal force until the upper end of the wafer clamping mechanism 41 presses against the wafer 42, and under the combined action of the wafer supporting mechanism and the wafer clamping mechanism 41, the wafer 42 is firmly clamped; and when the wafer rotating base 4 stops, the wafer clamping mechanism 41 releases the wafer 42, and at this moment, the wafer 42 also stops, that is, the wafer 42 is no longer pressed by the wafer clamping mechanism 41 and will not rotate away from the wafer rotating base 4.

### Embodiment 1

As shown in FIG. 4, a clutch structure is arranged between the upper mechanism 3 and the lower mechanism 2. In a power-on condition, the lower mechanism 2 is in noncontact transmission connection with the upper mechanism 3 by means of the clutch structure, such that the lower mechanism 2 can drive the upper mechanism 3 to rotate synchronously.

Specifically, the clutch structure comprises contact surfaces 51 and 52 which are respectively arranged on the upper mechanism 2 and the lower mechanism 3, and an electromagnetic induction assembly 53, wherein the electromagnetic induction assembly 53 comprises electromagnets 531 arranged on the lower mechanism 2 at intervals and permanent magnets 532 arranged on the upper mechanism 3 at intervals, the permanent magnets 532 and the electromagnets 531 are the same in magnetic polarity, and the permanent magnets 532 and the electromagnets 531 are arranged alternately. When the electromagnetic induction assembly 53 is powered on, a repelling force will be generated between the lower mechanism 2 and the upper mechanism 3, and specifically, a repelling force will be generated between the permanent magnets 532 and the electromagnets 531 that are arranged alternately to circumferentially push the lower mechanism 2 and the upper mechanism 3 to rotate relatively to realize noncontact transmission connection between the lower mechanism 2 and the upper mechanism 3. Of course, the positions of the permanent magnets 532 and the positions of the electromagnets 531 may be exchanged.

Once the electromagnetic induction assembly 53 is powered off, the electromagnets 532 will be demagnetized, the repelling force between the permanent magnets 532 and the electromagnets 531 disappears, the repelling force between the contact surface 51 on the lower mechanism 2 and the contact surface 52 on the upper mechanism 3 disappears, and the lower mechanism 2 is no longer in transmission connection with the upper mechanism 3. At this moment, the lower mechanism 2 stops or rotates slowly, and the upper mechanism 3 continues to rotate under the action of inertia to stop gradually.

### Embodiment 2

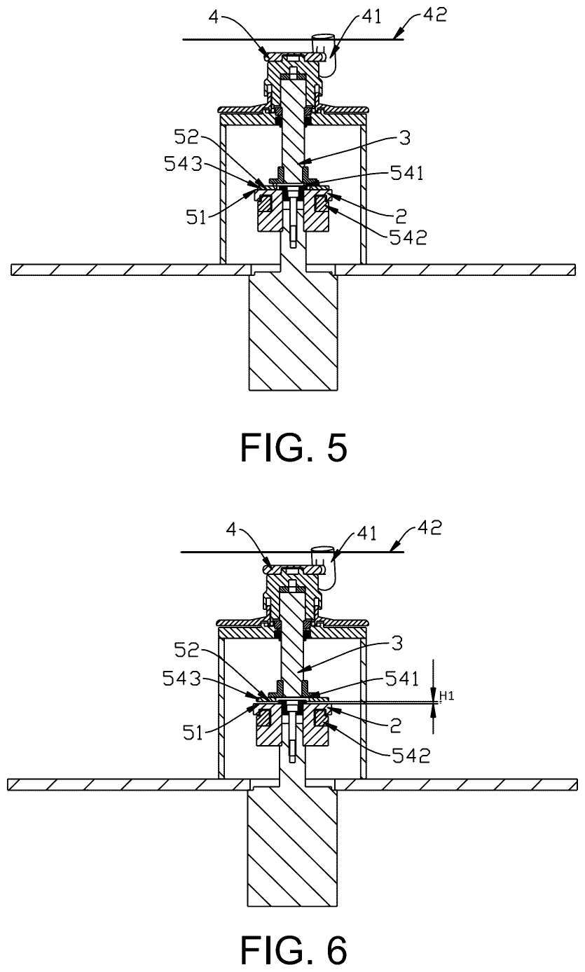

As shown in FIGS. 3, 5 and 6, a clutch structure is arranged between the upper mechanism 3 and the lower mechanism 2. In a power-on condition, the lower mechanism 2 is in contact transmission connection with the upper mechanism 3 by means of the clutch structure, such that the lower mechanism 2 can drive the upper mechanism 3 to rotate synchronously.

Specifically, the clutch structure comprises contact surfaces 51 and 52 which are respectively arranged on the lower mechanism 2 and the upper mechanism 3, magnets 542 and metal parts 543 which are respectively arranged on the lower mechanism 2 and the upper mechanism 3, and a reset element 541. In this embodiment, the magnets 542 are located on the lower mechanism 2 and are electromagnetic coils, the metal parts 543 are located on the upper mechanism 3, and the reset element 541 is connected between the upper mechanism 3 and the metal parts 543. Of course, in other embodiments, the positions of the magnets 542 and the positions of the metal parts 543 may be exchanged.

In the power-on condition, the magnets 542 overcome an elastic force of the reset element 541 to attract the metal parts 543, and sufficient static friction is generated by the magnetic force to transfer the rotation torque of a motor to the wafer rotating base 4 to drive the wafer 42 to rotate with the power source 1.

Once power is cut off, the magnets 54 will be demagnetized instantly, the metal parts 543 move upwards under the action of the reset element 541, and the demagnetized magnets 54 are disconnected from the metal parts 543, as shown in FIG. 6, the contact surface 51 on the lower mechanism 2 is separated from the contact surface 52 on the upper mechanism 3, and the contact surface 51 and the contact surface 52 are spaced apart from each other by a distance of 0.1-1 mm, that is, H1=0.1-1 mm shown below. At this moment, the lower mechanism 2 is no longer in transmission connection with the upper mechanism 3, the lower mechanism 2 stops or rotates slowly, and the upper mechanism 3 continues to rotate under the action of inertia and stops gradually.

### Embodiment 3

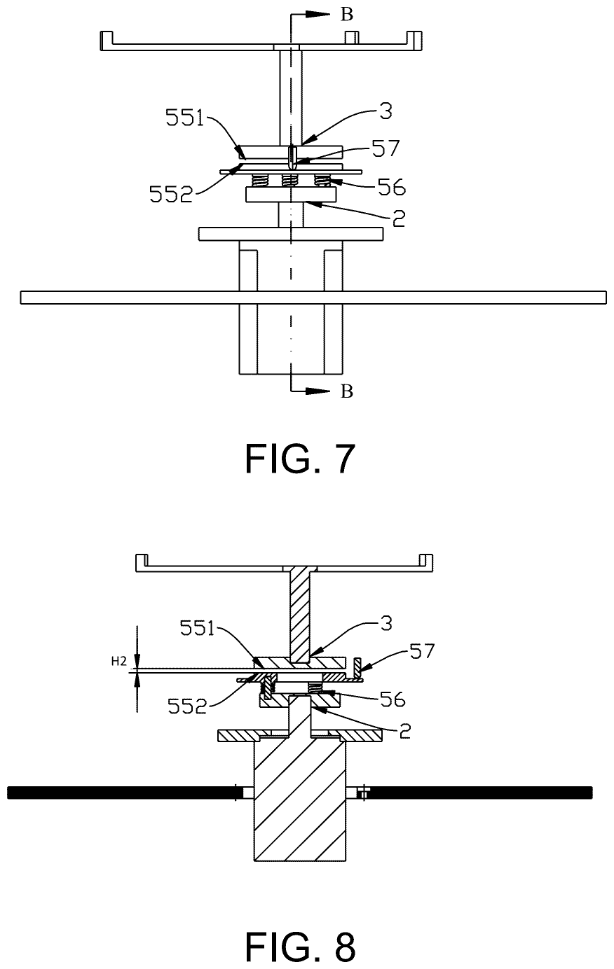

As shown in FIGS. 7-10, in this embodiment, a clutch structure also realizes contact transmission connection between the lower mechanism 2 and the upper mechanism 3.

Specifically, the clutch structure comprises a lower contact surface 552 arranged on the lower mechanism 2, a contact surface 551 arranged on the upper mechanism 3, elastic elements 56, and a push rod 57, wherein the elastic elements 56 drive the lower contact surface 552 to move upwards to come in contact with the upper contact surface 551 to realize transmission. In this embodiment, the upper contact surface 551 and the lower contact surface 552 are both friction discs, will not slide relatively in transmission connection, and approximately form a rigid body. The push rod 57 may move downwards to drive the lower contact surface 552 to move; or, the push rod 57 may move upwards to drive the upper contact surface 551 to move, and in this case, the elastic elements 56 match the upper contact surface 551. In this embodiment, the push rod 57 drives the lower contact surface 552 to move.

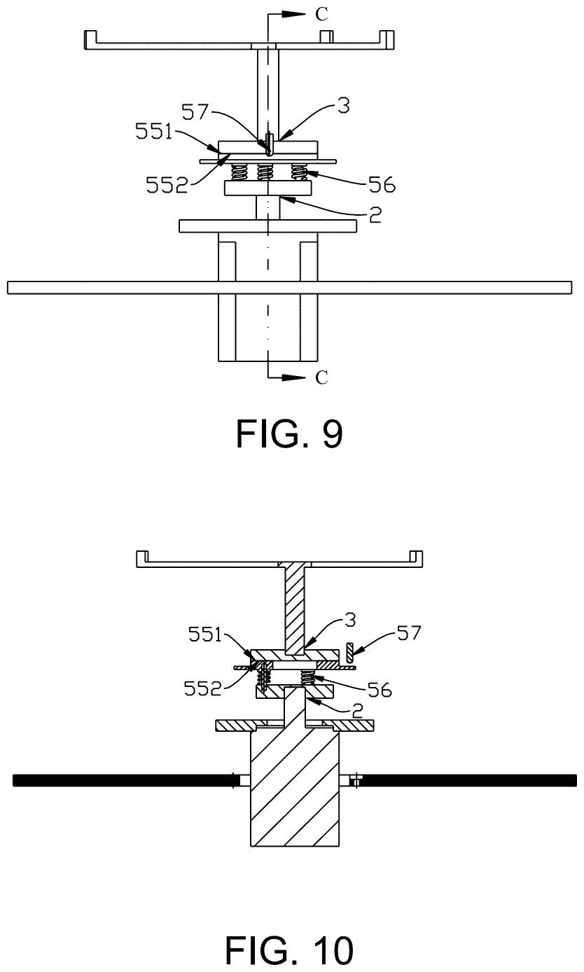

In a power-on condition, the push rod 57 retracts under the action of a cylinder, that is, the push rod 57 is spaced apart from the lower contact surface 552 by a certain distance, which means that there is no force between the push rod 57 and the lower contact surface, as shown in FIGS. 9 and 10.

In a power-off condition, the push rod 57 drives the lower contact surface 552 to move downwards under the action of the cylinder, and the elastic elements 56 are compressed, such that the upper contact surface 551 and the lower contact surface 552 are separated from each other, that is, transmission will not occur between the upper contact surface 551 and the lower contact surface 552, and the upper contact surface 551 and the lower contact surface 552 are spaced apart from each other by a distance of 0.1-5 mm, that is, H2=0.1-5 mm in FIG. 8. At this moment, the lower mechanism 2 stops or rotates slowly, and the upper mechanism 3 continues to rotate under the action of inertia and stops gradually.

The cylinder for driving the push rod 57 may be a single-acting cylinder, and in this case, an electromagnetic valve connected to the cylinder is a normally open valve; in the operation state, air cannot enter the cylinder, and the push rod 57 retracts under the action of an internal spring; and when power is cut off, air enters the cylinder via the electromagnetic valve, the push rod 57 stretches out under the action of the air pressure to separate the upper contact surface 551 from the lower contact surface 552. The cylinder for driving the push rod 57 may be a double-acting cylinder, and in this case, an electromagnetic valve connected to the cylinder is an electric control two-position five-way electromagnetic valve; in the operation state, the push rod 57 retracts under the action of the air pressure; and when power is cut off, the electromagnetic valve switches the direction of the air flow to push the push rod 57 to stretch out to separate the upper contact surface 551 from the lower contact surface 552.

### Embodiment 4

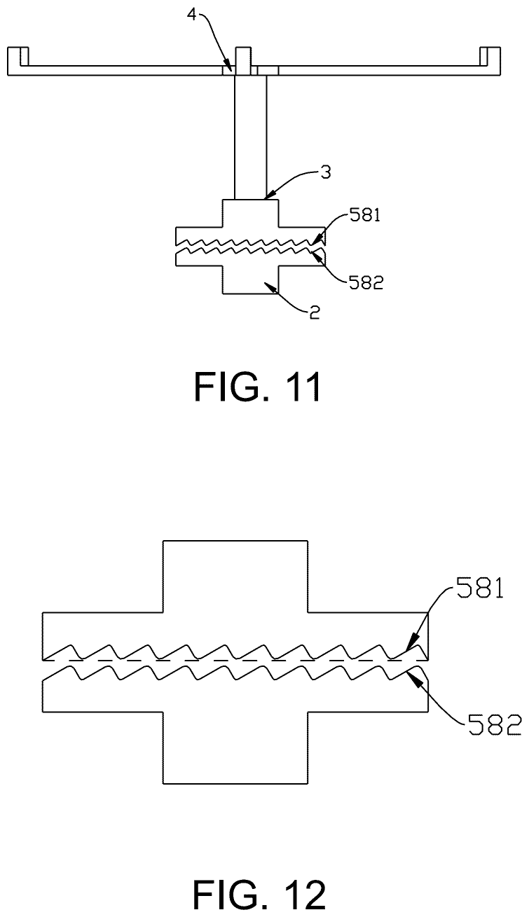

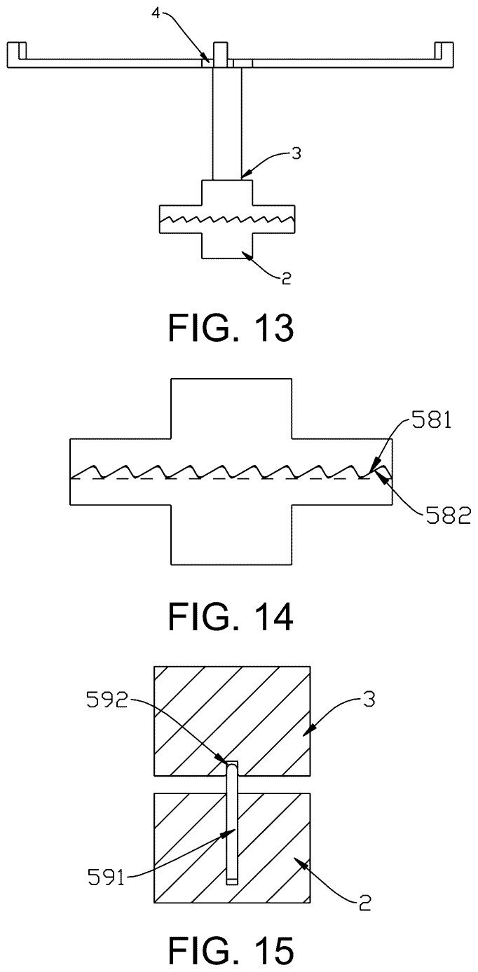

As shown in FIGS. 11-14, in this embodiment, a clutch structure also realizes contact transmission connection between the lower mechanism 2 and the upper mechanism 3.

Specifically, the clutch structure comprises an upper toothed disc 581 arranged on the upper mechanism 3 and a lower toothed disc 582 arranged on the lower mechanism 2, the upper toothed disc 581 engages with the lower toothed disc 582 to realize transmission, and a thrust exists between toothed surfaces of the upper toothed disc 581 and the lower toothed disc 582.

When the lower toothed disc 582 stops, the upper toothed disc 581 continues to rotate anticlockwise along a left slope.

In the operation state, the lower toothed disc 582 engages with the upper toothed disc 581 under the action of a bottom support force, the power source 1 drives the lower toothed disc 582 to rotate, and at this moment, the lower toothed disc 582 drives the upper toothed disc 581 to rotate in the same direction by means of a resultant force of the thrust and friction between the toothed surfaces on a right slope. When power is cut off, the lower toothed disc 582 disengages from the upper toothed disc 581 along the slopes, such that the upper mechanism 3 will not be affected by the braking force of a motor.

### Embodiment 5

As shown in FIG. 15, in this embodiment, a clutch structure also realizes contact transmission connection between the lower mechanism 2 and the upper mechanism 3.

Specifically, the clutch structure comprises a push rod 591 and a groove 592 which are respectively arranged on arranged on the upper mechanism 3 and the lower mechanism 2. In the operation state, the push rod 591 is inserted into the groove 592, and the rotation torque of the power source 1 is transmitted by means of a side surface of the push rod 591 and a mating surface of the groove 592 to drive the upper mechanism 3 to rotate. When power is cut off, the push rod 591 is drawn out of the groove 592, such that the upper mechanism 3 will not be affected by the braking force of a motor.

An opening of the groove 592 is chamfered, and a chamfer or an arc surface is designed at the top of the push rod 591, such that the push rod 591 can be smoothly inserted into the groove 592.

### Embodiment 6

A wafer drying system comprises the wafer rotating and clamping mechanism adopting any one of the abovementioned structures. Other structures of the wafer drying system belong to the prior art and will not be repeated here.

### Embodiment 7

A wafer cleaning system comprises the wafer rotating and clamping mechanism adopting any one of the abovementioned structures. Other structures of the wafer cleaning system belong to the prior art and will not be repeated here.

### Embodiment 8

A single wafer cleaner has both a wafer cleaning function and a wafer drying function, and comprises the wafer rotating and clamping mechanism adopting any one of the abovementioned structures. Other structures of the single wafer cleaner belong to the prior art and will not be repeated here.

The above specific embodiments are used for explaining the invention, and are not intended to limit the invention. Any modifications and transformations made to the invention based on the spirit of the invention and within the protection scope of the claims should fall within the protection scope of the invention.

1. A wafer rotating mechanism, comprising:
a lower mechanism configured to output rotating power; and
an upper mechanism connected to a wafer rotating base;
wherein the upper mechanism and the lower mechanism have an operation state and a separation state; in the operation state, the upper mechanism is rotated by the lower mechanism; in the separation state, the upper mechanism is separated from the lower mechanism;
wherein under a power-off condition, the upper mechanism and the lower mechanism are switched from the operation state to the separation state, and the upper mechanism drives the wafer rotating base to rotate under inertia until the upper mechanism stops.

2. The wafer rotating mechanism according to claim 1, wherein the lower mechanism and a power source are arranged separately, and the lower mechanism is able to rotate with the power source.

3. The wafer rotating mechanism according to claim 1, wherein under the power-off condition, the lower mechanism stops outputting the rotating power.

4. The wafer rotating mechanism according to claim 1, wherein a clutch structure is arranged between the upper mechanism and the lower mechanism, and under a power-on condition, the lower mechanism and the upper mechanism are connected by a non-contact transmission connection through the clutch structure, such that the lower mechanism drives the upper mechanism to rotate synchronously.

5. The wafer rotating mechanism according to claim 4, wherein the clutch structure comprises contact surfaces which are respectively disposed on the lower mechanism and the upper mechanism, and an electromagnetic induction assembly, and when the electromagnetic induction assembly is powered on, a repelling force is generated between the lower mechanism and the upper mechanism to realize the non-contact transmission connection between the lower mechanism and the upper mechanism.

6. The wafer rotating mechanism according to claim 5, wherein the electromagnetic induction assembly comprises electromagnets arranged at intervals on the lower mechanism and permanent magnets arranged at intervals on the upper mechanism, and the permanent magnets and the electromagnets are the same in magnetic polarity and are arranged alternately.

7. The wafer rotating mechanism according to claim 1, wherein a clutch structure is arranged between the upper mechanism and the lower mechanism, and the lower mechanism and the upper mechanism are connected by a contact transmission connection through the clutch structure, such that the lower mechanism drives the upper mechanism to rotate synchronously.

8. The wafer rotating mechanism according to claim 7, wherein the clutch structure comprises a magnet and a metal part which are respectively arranged on the upper mechanism and the lower mechanism, and a reset element, and under the power-off condition, the magnet is disconnected from the metal part.

9. The wafer rotating mechanism according to claim 7, wherein the clutch structure comprises an upper contact surface arranged on the upper mechanism, a lower contact surface arranged on the lower mechanism, an elastic element and a push rod, and the elastic element drives the lower contact surface and the upper contact surface to come in contact for transmission; and under the power-off condition, the push rod drives the lower contact surface or the upper contact surface to compress the elastic element to separate the upper contact surface from the lower contact surface.

10. The wafer rotating mechanism according to claim 7, wherein the clutch structure comprises an upper toothed disc disposed on the upper mechanism and a lower toothed disc disposed on the lower mechanism, and the upper toothed disc engages with the lower toothed disc for transmission.

11. The wafer rotating mechanism according to claim 7, wherein the clutch structure comprises a push rod and a groove which are respectively arranged on the upper mechanism and the lower mechanism, and under the power-off condition, the push rod disengages from the groove to separate the upper mechanism from the lower mechanism.

12. The wafer rotating mechanism according to claim 1, wherein in the separation state, a distance between the upper mechanism and the lower mechanism ranges between 0.1-5 mm.

13. A wafer rotating and clamping mechanism, comprising the wafer rotating mechanism according to claim 1, a wafer rotating base, a wafer supporting mechanism arranged on a periphery of the wafer rotating base, and a wafer clamping mechanism, wherein in the power-off condition, the upper mechanism and the lower mechanism are switched from the operation state to the separation state, the upper mechanism drives the wafer rotating base to rotate under inertia, wherein the wafer clamping mechanism is kept under a centrifugal force, a bottom of the wafer clamping mechanism moves outwards, and an end of the wafer clamping mechanism presses against a wafer to fix the wafer together with the wafer supporting mechanism, until the wafer rotating base stops rotating, and the rotating clamping mechanism releases the wafer.

14. A wafer drying system, comprising the wafer rotating and clamping mechanism according to claim 13.

15. A wafer cleaning system, comprising the wafer rotating and clamping mechanism according to claim 13.
